(19) United States
(12) Patent Application Publication
(10) Pub. No.: US 2025/0131172 A1
(43) Pub. Date: Apr. 24, 2025

(54) Negative Group Delay Filters based on Reciprocal-capped Butterworth, and Reciprocal-capped Chebyshev low-pass filter transfer functions

(71) Applicant: Miodrag Kandic, Portage la Prairie (CA)

(72) Inventor: Miodrag Kandic, Portage la Prairie (CA)

(21) Appl. No.: 18/491,922

(22) Filed: Oct. 23, 2023

(51) Int. Cl. G06F 30/327; G06F 17/17

(52) U.S. Cl. CPC G06F 30/327; G06F 17/17

(57) ABSTRACT

Negative Group Delay (NGD) filter circuit designs are presented, based on reciprocal transfer functions of classic low-pass Butterworth and Chebyshev filters. The NGD designs exhibit a frequency-domain transfer function magnitude response within the specified bandwidth that is either maximally flat (for reciprocal-Butterworth design), or with a prescribed ripple (for reciprocal-Chebyshev design). The step-by-step design process synthesizes the transfer function for 4 user-specified design parameters: (a) carrier/center frequency f₀; (b) bandwidth around the center frequency Δf, and (c) two out of the following three parameters (i) number of stages, or order of the design, N; (ii) the trade-off attenuation at center frequency (or alternatively, out-of-band gain relative to the center frequency magnitude), A; (iii) NGD at center frequency. The reciprocal-Chebyshev design has an additional user-specified design parameter: magnitude of the ripple response within the bandwidth (between 0 dB and 3dB). Synthesized transfer functions are demonstrated via three different circuit topologies.

### TECHNICAL FIELD

The present disclosure relates generally to negative group delay (NGD) circuits, and more particularly, to NGD circuits for use in, for example, delay compensation (or delay reduction) for a signal transmitted through a communication channel, group delay equalization over a frequency band (to reduce transmitted signal distortion), constant phase transmission lines, beam squint minimization in antenna phased arrays, among others.

### BACKGROUND

All NGD circuits exhibit a common property in the time domain, that certain features of a waveform transmitted through such circuits (such as a peak of a pulse) get time-advanced (negatively delayed) at the output, relative to the input (i.e., pulse peak appears at the output before it is fully formed at the input). In that sense, NGD circuits essentially use early parts of the applied waveform, to “predict” the overall shape of the rest of the waveform, and therefore do not violate the principle of causality. For the NGD property to exhibit itself, the applied waveform needs to satisfy certain conditions (such as no additional discontinuities in the waveform or its derivatives, in between the turn-on/off points, i.e., it applies to a smooth waveform).

In the frequency domain, NGD circuits exhibit a slope of their transfer function phase, which is the opposite to the phase slope of most common telecommunication electrical components, such as transmission lines for example, and therefore can be used to produce a phase slope cancellation, i.e., constant-phase transmission lines (which can be used in antenna phased arrays, as mentioned).

The major trade-off that accompanies NGD circuits is attenuation within transmitted signal's frequency bandwidth, and this attenuation is proportional to the time-advancement (NGD) achieved. The signal attenuation can be compensated via amplifiers, which also amplify the transients associated with the signal turn-on/off points. Therefore, to keep the transients below an acceptable level (for example below the level of the signal peak), as well as to keep the attenuated signal above the noise present in the communication system, there is a certain maximum level of the mentioned signal attenuation (NGD trade-off) that can be practically tolerated. In turn, this puts practical limitations on the extent of NGD that can be achieved for a given signal waveform and given communication channel.

The NGD circuits have attracted a considerable interest, resulting in numerous design publications during a period of over two decades, to date. The reported designs can be roughly classified into two categories: those involving lumped RLC resonators (consisting of resistors, inductors, capacitors), and those involving distributed circuits at microwave frequencies (consisting of resistors only, and distributed elements such as transmission lines on Printed Circuit Boards, and various conductor geometries inserted in either the signal traces or the ground plane).

To increase the bandwidth of an NGD design, and to achieve a desired shape of a frequency transfer function describing the response of the design, often multiple stages of similar NGD circuit topology are used, which are individually tuned at somewhat different frequencies in the vicinity of the overall design center frequency. Further, each stage also has its own individual bandwidth, and attenuation at its particular tuned frequency. This brings the number of variable parameters (degrees of freedom) of each stage to three (tuned frequency, bandwidth, attenuation), and for designs with multiple stages (three or more for example) it results in a large number of parameters that can be potentially tweaked to achieve the overall desired transfer function response. The range over which each of the parameters can be scanned, and a small step of varying the parameters, makes the trial-and-error tweaking design quite cumbersome and impractical.

It would be useful if an NGD design process could be developed to remove the parameter tweaking and trial-and-error approach, to achieve a desired shape/response of the design's transfer function.

Further, NGD designs are accompanied with a trade-off signal attenuation, which is proportional to the desired NGD. For a given bandwidth and tolerable attenuation, it would be useful to have a design process (and eventually circuit topology implementation) that would achieve highest possible values of NGD.

### SUMMARY

The presented reciprocal-Butterworth and reciprocal-Chebyshev designs address both of desired properties for NGD circuits mentioned above: (a) a clear step-by-step design process to synthesize a desired transfer function for given user parameters (either a flat-magnitude transfer function response within the bandwidth for reciprocal-Butterworth, or a prescribed-ripple level magnitude response for reciprocal-Chebyshev); and (b) relatively compared to other reported designs, a high NGD value at center frequency for a given bandwidth, attenuation and number of stages for the described reciprocal-Butterworth design, and even higher NGD for reciprocal-Chebyshev design.

The embodiments listed below are based on assumed 4 designer-specified design parameters: (a) carrier/center frequency f₀; (b) bandwidth around the center frequency Δf, and (c) two out of the following three parameters (i) number of stages, or order of the design, N; (ii) the trade-off attenuation at center frequency (or alternatively, out-of-band gain relative to the center frequency magnitude), A; (iii) NGD at center frequency. The final embodiment (reciprocal-Chebyshev design) has an additional user-specified design parameter: magnitude of the ripple response within the bandwidth (between 0 dB and 3 dB).

According to one embodiment there is described an Intermediate Transfer Function Synthesis at Frequency Baseband (Centered Around Zero Frequency) for what is referred to herein as reciprocal-capped Butterworth design.

According to another embodiment there is described a Final Transfer Function Synthesis Centered Around Non-Zero Frequency for reciprocal-capped Butterworth design. The Final Transfer Function Synthesis Centered Around Non-Zero Frequency may be implemented with electric circuit designs including, without limitation:
an Exact NGD Transfer Function (Around Non-Zero Frequency) Implementation of reciprocal-capped Butterworth design by employing RLC resonators in a Sallen-Key Circuit Topology;
an Approximate NGD Transfer Function (Around Non-Zero Frequency) Implementation of reciprocal-capped Butterworth design by employing RLC resonators in a Passive Ladder Topology;
an Approximate NGD Transfer Function (Around Non-Zero Frequency) Implementation of reciprocal-capped Butterworth design by employing Microwave Circuit Quarter-Wavelength Transmission Lines and Resistors only.

In accordance with yet another embodiment there is described a Reciprocal-capped Chebyshev design variation (its baseband/intermediate transfer function replaces the corresponding Reciprocal-Butterworth transfer function in Section 1, then the same process followed as in Sections 2-5 to establish the final Reciprocal-Chebyshev transfer function around non-zero frequency, and to implement that transfer function via the same three described circuit topologies: Sallen-Key with parallel RLC resonators, Passive Ladder with parallel and series RLC resonators, and Microwave circuit with quarter-wavelength lines and resistors only). The Reciprocal-capped Chebyshev design variation may also be implemented with other electric circuit designs. The reciprocal-Chebyshev design has an additional designer-specified parameter: magnitude of the ripple response within the bandwidth (between 0 dB and 3 dB).

### DESCRIPTION OF THE DRAWINGS

Preferred exemplary embodiments will hereinafter be described in conjunction with the appended drawings wherein like designations denote like elements, and wherein:

FIG. 1 is a diagrammatic and schematic illustration of an Example 5^{th}-order transfer function magnitude as a function of frequency, of the proposed Reciprocal-Butterworth NGD baseband design, with parameters A=100 (A_{dB}=40 dB), N=5, ω_{c}1=1, ω (2=A^{1/N}=2.512.

FIG. 2A is a diagrammatic and schematic illustration of the transfer function magnitude vs frequency, of the Proposed reciprocal-Butterworth baseband NGD design with chosen out-of-band gain A=100 (40 dB) and N=1,2,3,4 order.

FIG. 2B is a diagrammatic and schematic illustration of the transfer function group delay plots vs frequency, of the Proposed reciprocal-Butterworth baseband NGD design with chosen out-of-band gain A=100 (40 dB) and N=1,2,3,4 order.

FIG. 3 is a diagrammatic and schematic illustration of an Input Gaussian pulse as a function of time, with a frequency spectrum cut-off at ω_{c}=1, and the corresponding gain-compensated output waveform y (t) of the proposed reciprocal-Butterworth design with out-of-band gain A=40 dB, and order N=12. The output pulse peak (solid blue curve) precedes the input peak (negative delay) by almost a full standard deviation (2.694s vs 3s).

FIG. 4 is a diagrammatic and schematic illustration of a Sallen-Key topology that can be used to achieve the exact 3^{rd}-order reciprocal-Butterworth baseband NGD transfer function translated to a higher center frequency ω₀ (BSF).

FIG. 5A is a diagrammatic and schematic illustration of a transfer function magnitude as a function of frequency, of the ideal source (buffered) driven reciprocal-Butterworth Sallen-Key design, and of the shunt resistor matched design variation driven by a 5002 source.

FIG. 5B is a diagrammatic and schematic illustration of a transfer function group delay as a function of frequency, of the ideal source (buffered) driven reciprocal-Butterworth Sallen-Key design, and of the shunt resistor matched design variation driven by a 5002 source.

FIG. 6 is a diagrammatic and schematic illustration of a Three-resonator π-circuit ladder topology that can achieve an approximate 3^{rd}-order baseband reciprocal-Butterworth NGD transfer function translated to a higher center frequency 00 (BSF).

FIG. 7A is a diagrammatic and schematic illustration of a transfer function magnitude as a function of frequency, of the exact reciprocal-Butterworth 3^{rd}-order design upshifted to a higher center frequency, and of the π-circuit all-passive design.

FIG. 7B is a diagrammatic and schematic illustration of a transfer function group delay as a function of frequency, of the exact reciprocal-Butterworth 3^{rd}-order design upshifted to a higher center frequency, and of the π-circuit all-passive design.

FIG. 8 is a diagrammatic and schematic illustration of a Five-resonator ladder topology that can be used to achieve an approximate 5^{th}-order baseband reciprocal-Butterworth NGD transfer function translated to a higher center frequency ω₀ (BSF).

FIG. 9 is a diagrammatic and schematic illustration of a Three-stub microwave topology that can achieve an approximate 3^{rd}-order baseband reciprocal-Butterworth NGD transfer function translated to a higher center frequency ω₀ (BSF).

FIG. 10A is a diagrammatic and schematic illustration of a transfer function magnitude as a function of frequency, of the exact reciprocal-Butterworth 3^{rd}-order design upshifted to a higher center frequency, and of the three-stub microwave design.

FIG. 10B is a diagrammatic and schematic illustration of a transfer function group delay as a function of frequency, of the exact reciprocal-Butterworth 3^{rd}-order design upshifted to a higher center frequency, and of the three-stub microwave design.

FIG. 11A is a diagrammatic and schematic illustration of the transfer function magnitude as a function of frequency, of the proposed Reciprocal-capped Chebyshev design, with Example design parameters 3^{rd}-order 3 dB ripple design (8=1), A=10 (A_{dB}=10 dB).

FIG. 11B is a diagrammatic and schematic illustration of the transfer function magnitude as a function of frequency, of the proposed Reciprocal-capped Chebyshev design, with Example design parameters 5^{th}-order 1 dB ripple (ε=0.5088), A=100 (A_{dB}=40 dB) design.

FIG. 12A is a diagrammatic and schematic illustration of the transfer function magnitude vs frequency of the proposed Reciprocal-capped Chebyshev baseband NGD design with chosen out-of-band gain A=100 (40 dB), 3^{rd} order (N=3), with 0.5-3 dB varied baseband ripple.

FIG. 12B is a diagrammatic and schematic illustration of the transfer function group delay vs frequency of the proposed Reciprocal-capped Chebyshev baseband NGD design with chosen out-of-band gain A=100 (40 dB), 3^{rd} order (N=3), with 0.5-3 dB varied baseband ripple.

FIG. 13A is a diagrammatic and schematic illustration of the transfer function magnitude of an exact reciprocal-Chebyshev 3^{rd}-order design upshifted to a higher center frequency, and of the π-circuit all-passive design.

FIG. 13B is a diagrammatic and schematic illustration of the group delay of an exact reciprocal-Chebyshev 3^{rd}-order design upshifted to a higher center frequency, and of the π-circuit all-passive design.

### DETAILED DESCRIPTION

Referring to the Figures, there is described implementation of the synthesized transfer function presented for three different circuit types.

### 1. Intermediate Transfer Function Synthesis at Frequency Baseband (Centered Around Zero Frequency) for Reciprocal-Capped Butterworth Design

For an applied sinusoidal input voltage with angular frequency ω=2π·f, a transfer function H(jω) of an electrical circuit represents a ratio between the output and input sinusoidal voltages, given as a complex number (j represents the imaginary part) to capture the ratio of sinusoidal amplitudes, as well as their phases.

NGD filters exhibit a property that their transfer function magnitude has a minimum at the design/center frequency, which then translates into the transfer function phase having a positive slope, and its Group Delay, as a negative derivative of the phase with respect to frequency, is negative within a finite region around the center frequency. In the time domain, when certain pulse voltage waveforms are applied, this corresponds to the pulse peak appearing at the output before the pulse peak forms at the input, i.e. negative delay.

The novel NGD transfer function design presented here, is based on a reciprocal function of a classic N^{th} order low-pass Butterworth filter transfer function, and multiplied by what is referred to here as a “capping” function, which is another N^{th} order low-pass Butterworth filter transfer function but with a wider bandwidth relative to the first one:

$$H ( j ω ) = {H}_{reciprocal - LP} ( j ω ) \cdot {H}_{capping - LP} ( j ω ) = \frac{1}{{H}_{L P} ( j \frac{ω}{{ω}_{c 1}} )} \cdot {H}_{L P} ( j \frac{ω}{{ω}_{c 2}} ) . \qquad ( 1 )$$

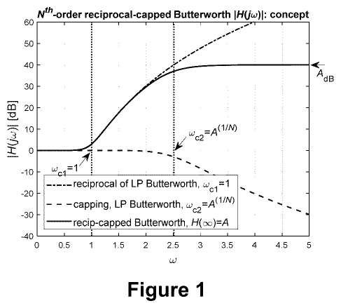

The concept of such novel NGD reciprocal-capped Butterworth filter transfer function, is captured in the magnitude plot in FIG. 1. The final transfer function, shown in red, exhibits the mentioned minimum at the zero-center frequency (baseband design), while at the same having a flat magnitude response within the bandwidth around the center frequency, which is characteristic to Butterworth filters.

From expression (1), using the transfer function expressions of classic Butterworth filters, the novel NGD design for even and odd values of the order N, are given respectively as (frequency ω in the expressions below is normalized to user-specified cut-off frequency value ω_{c}=2π·Δf/2):

$${H}_{N - e v e n} ( j ω ) = {\prod }_{k = 1}^{N / 2} ( \frac{{ω}^{2} - j {g}_{k} ω - 1}{{( \frac{ω}{{A}^{1 / N}} )}^{2} - {jg}_{k} \frac{ω}{{A}^{1 / N}} - 1} ) = A {\prod }_{k = 1}^{N / 2} ( \frac{{ω}^{2} - {jg}_{k} ω - 1}{{ω}^{2} - j {g}_{k} {A}^{1 / N} ω - {A}^{2 / N}} ) , \qquad ( 2 a )$$

$${H}_{N - o d d} ( j ω ) = A \frac{ω - j}{ω - j {A}^{1 / N}} {\prod }_{k = 1}^{( N - 1 ) / 2} ( \frac{{ω}^{2} - {jg}_{k} ω - 1}{{ω}^{2} - j {g}_{k} {A}^{1 / N} ω - {A}^{2 / N}} ) , \qquad ( 2 b )$$

where the factorized functions' parameters gₖ are as in N^{th}-order Butterworth low pass filter:

$${g}_{k} = 2 \cdot sin ( \frac{2 k - 1}{2 N} π ) \qquad ( 2 c )$$

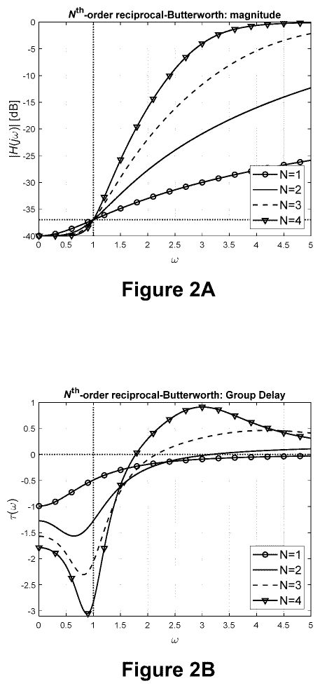

Expressions (2a-2b) can also be divided by the out-of-band gain A, to represent their scaled (or on dB magnitude plot, translated downward), gain-uncompensated version with center frequency magnitude attenuation 1/A (=A_{dB}), and their out-of-band magnitude characteristic always less than 1 (below 0 dB). Such magnitude plots are shown in FIG. 2(a) for several different design orders. Corresponding group delay plots are shown in FIG. 2(b), confirming negative delay values at the center zero-frequency.

From expressions (2a-2b), after division by assumed out-of-band gain A to get a purely passive design, transfer functions for the first five orders of the proposed design are given by:

$${H}_{1} ( j ω ) = ( \frac{ω - j}{ω - j A} ) , \qquad ( 3 a )$$

$${H}_{2} ( j ω ) = \frac{{ω}^{2} - j \sqrt{2} ω - 1}{{ω}^{2} - j \sqrt{2} \sqrt{A} ω - A} , \qquad ( 3 b )$$

$${H}_{3} ( j ω ) = ( \frac{ω - j}{ω - j {A}^{1 / 3}} ) \cdot ( \frac{{ω}^{2} - j ω - 1}{{ω}^{2} - j {A}^{1 / 3} ω - {A}^{2 / 3}} ) , \qquad ( 3 c )$$

$${H}_{4} ( j ω ) = ( \frac{{ω}^{2} - j 2 sin ( \frac{π}{8} ) ω - 1}{{ω}^{2} - j 2 sin ( \frac{π}{8} ) {A}^{1 / 4} ω - {A}^{2 / 4}} ) \cdot ( \frac{{ω}^{2} - j 2 sin ( \frac{3 π}{8} ) ω - 1}{{ω}^{2} - j 2 sin ( \frac{3 π}{8} ) {A}^{1 / 4} ω - {A}^{2 / 4}} ) , \qquad ( 3 d )$$

$${H}_{5} ( j ω ) = ( \frac{ω - j}{ω - j {A}^{1 / 5}} ) \cdot ( \frac{{ω}^{2} - j 2 sin ( \frac{π}{10} ) ω - 1}{{ω}^{2} - j 2 sin ( \frac{π}{10} ) {A}^{1 / 5} ω - {A}^{2 / 5}} ) \cdot ( \frac{{ω}^{2} - j 2 sin ( \frac{3 π}{10} ) ω - 1}{{ω}^{2} - j 2 sin ( \frac{3 π}{10} ) {A}^{1 / 5} ω - {A}^{2 / 5}} ) . \qquad ( 3 e )$$

Classic low-pass Butterworth filter transfer function have a 3 dB magnitude difference between center frequency and band-edge (at normalized ω=1) values. For the NGD design presented here, as a ratio of two low-pass Butterworth transfer functions, a frequency correction factor is needed to preserve that 3 dB difference at ω=1, by replacing ω by ω/C_{ω-3dB}, in all H(jω) expressions above, where:

$${C}_{ω - 3 dB} = {( 1 - \frac{2}{{A}^{2}} )}^{\frac{1}{2 N}} . \qquad ( 4 )$$

For example, if A=100 (40 dB) then the correction factor for order N=1 yields C_{ω-3dB}=0.9999, and for higher orders it is even closer to 1.0, which renders the correction factor negligible for this relatively high value of out-of-band gain. A lower out-of-band gain of A=3.1623 (10 dB) for example, yields C_{ω-3dB}=0.8944, 0.9457, 0.9635 for N=1,2,3 respectively, and it needs to be considered.

The group delay at the center frequency, as a function of the out-of-band gain A and circuit order N, is derived to be:

$$τ ( 0 ) = - \frac{1}{{C}_{ω - 3 dB}} ( 1 - \frac{1}{{A}^{1 / N}} ) {\sum }_{k = 1}^{N} sin ( \frac{2 k - 1}{2 N} π ) . \qquad ( 5 )$$

In the FIG. 2b) examples with A=100 (40 dB), expression (5) yields center frequency NGD values, NGD=−τ(0)=0.9901s, 1.2729s, 1.5692s, 1.7868s for N=1,2,3,4, respectively.

As mentioned in the Abstract (and/or Summary, Background, Technical Field-if the user-specified design parameters end up being mentioned in one or more sections other than just currently appearing in the Abstract), two out of these three parameters need to be specified: order N, out-of-band gain A, NGD at center frequency NGD=−τ(0). If NGD is one of the specified parameters, then expression (5) can be used to back-solve for either A if Nis given, or to solve for Nif A is given.

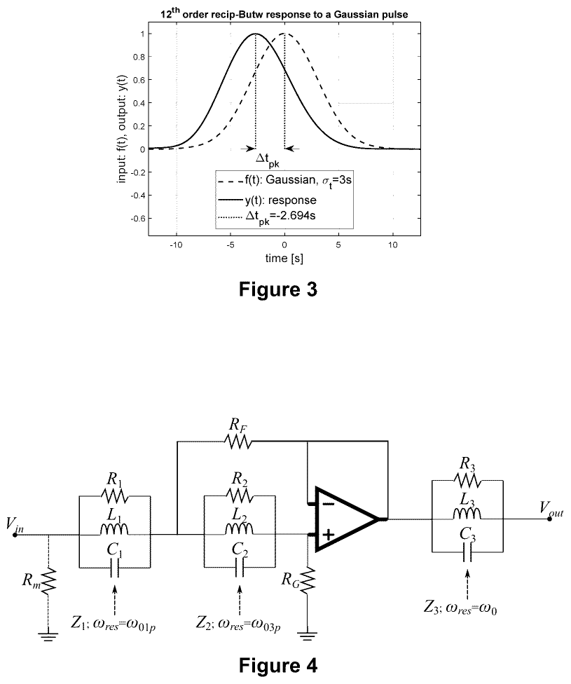

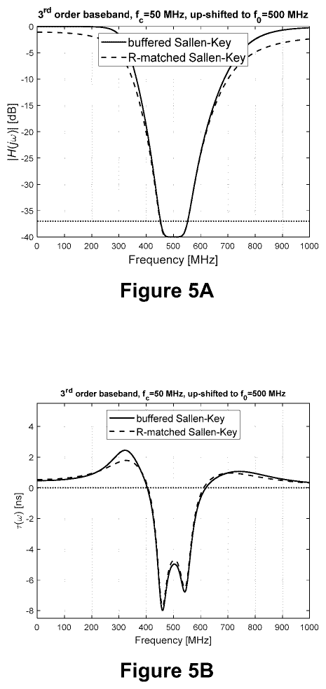

In the frequency domain, the proposed designed expressed via its intermediate transfer function at baseband (around zero center frequency), is given by the general form (2a-2b) and specific order N selected examples (3a-3e). In the time domain, the effect of a proposed design on a Gaussian pulse propagation is illustrated in FIG. 3, for a 12th order design (to show a substantial output pulse peak advancement relative to the input pulse peak). The input and output pulses correspond to a normalized bandwidth cut-off frequency ωc=2πf_{c}=1, and the time on horizontal axis can be inverse-proportionally scaled to any other cut-off frequency.

NGD circuits do not violate causality, since the pulse turn-on instance in time is not negatively delayed at the output; it is only the pulse peak at the output that gets advanced in time, based on pulse reshaping property of NGD circuits. This is possible for smooth pulses, where after the turn-on time the pulse voltage as a function of time, and its derivatives, are continuous.

### 2. Final Transfer Function Synthesis Centered Around Non-Zero Frequency

To shift an NGD-exhibiting baseband transfer function to its non-zero center frequency ω₀ equivalent, which is essentially a Band-Stop Filter (BSF) with a finite band-stop attenuation, the same frequency transformation that transforms a low-pass filter to its bandpass equivalent is applied (both ω and ω₀ are normalized to the baseband 3-dB cut-off frequency ωcl):

$$ω \to \frac{1}{2} ( ω - \frac{{ω}_{0}^{2}}{ω} ) . \qquad ( 6 )$$

As an example, consider a 3^{rd}-order reciprocal-Butterworth baseband transfer function exhibiting NGD given by (3c), with out-of-band gain A=100, or 40 dB (ω and all parameters are normalized to ω_{c}=1, with the 3-dB correction factor C_{ω-3dB}=(1-2/100²)^{1/6}≈1.0 in this case):

$${H}_{BB 3} ( j ω ) = ( \frac{ω - j}{ω - j 10 {0}^{1 / 3}} ) \cdot ( \frac{{ω}^{2} - j ω - 1}{{ω}^{2} - j 10 {0}^{1 / 3} ω - 10 {0}^{2 / 3}} ) . \qquad ( 7 a )$$

Employing expression (6), with the frequency up-shift to ω₀=10ω_{c}=10 chosen in this example, and employing factorization into 2^{nd} order function, yields:

$${H}_{BSF 3} ( j ω ) = \frac{{ω}^{2} - j 2 ω - {10}^{2}}{{ω}^{2} - j 9.2832 ω - {10}^{2}} ( \frac{{ω}^{2} - j 1.0864 ω - {10.9064}^{2}}{{ω}^{2} - j 6.4081 ω - {14.9294}^{2}} ) ( \frac{{ω}^{2} - j 0.9136 ω - {9.1704}^{2}}{{ω}^{2} - j 2.875 ω - {6.6982}^{2}} ) . \qquad ( 7 b )$$

In general, for the 2^{nd}-order baseband transfer function form that is a part of any odd or even N^{th}-order (given N>1) reciprocal-Butterworth transfer function presented in this paper, given by expressions (2a-2b), application of the frequency transformation given by expression (6) yields the following baseband/BSF pair of transfer functions:

$${H}_{BB 2} ( j ω ) = \frac{{ω}^{2} - j {Δω}_{1} ω - {ω}_{01}^{2}}{{ω}^{2} - j {Δω}_{2} ω - {ω}_{02}^{2}} , \qquad ( 8 a )$$

$${H}_{BSF 2} ( j ω ) = \frac{{( {ω}^{2} - {ω}_{0}^{2} )}^{2} - j 2 {Δω}_{1} ω ( {ω}^{2} - {ω}_{0}^{2} ) - 4 {ω}_{01}^{2} {ω}^{2}}{{( {ω}^{2} - {ω}_{0}^{2} )}^{2} - j 2 {Δω}_{2} ω ( {ω}^{2} - {ω}_{0}^{2} ) - 4 {ω}_{02}^{2} {ω}^{2}} . \qquad ( 8 b )$$

The factorized version of the 4^{th}-order function (8b) centered around frequency ω₀, which is more suitable for subsequent circuit design, is given by (the eight factorized parameters can be determined either numerically from 8b, or via derived explicit expressions):

$${H}_{BSF 2} ( j ω ) = ( \frac{{ω}^{2} - j {Δω}_{1 p} ω - {ω}_{01 p}^{2}}{{ω}^{2} - j {Δω}_{2 p} ω - {ω}_{02 p}^{2}} ) \cdot ( \frac{{ω}^{2} - j {Δω}_{3 p} ω - {ω}_{03 p}^{2}}{{ω}^{2} - j {Δω}_{4 p} ω - {ω}_{04 p}^{2}} ) . \qquad ( 8 c )$$

In general, for a 1st-order NGD baseband transfer function that is a part of any odd N^{th}-order reciprocal-Butterworth transfer function presented in this paper, application of the frequency transformation given by expression (6) yields the following baseband/BSF pair of transfer functions:

$${H}_{BB 1} ( j ω ) = \frac{ω - j {Δω}_{5}}{ω - j {Δω}_{6}} , \qquad ( 9 a )$$

$${H}_{BSF 1} ( j ω ) = \frac{{ω}^{2} - j {Δω}_{5 p} ω - {ω}_{0}^{2}}{{ω}^{2} - j {Δω}_{6 p} ω - {ω}_{0}^{2}} = \frac{{ω}^{2} - j 2 {Δω}_{5} ω - {ω}_{0}^{2}}{{ω}^{2} - j 2 {Δω}_{6} ω - {ω}_{0}^{2}} . \qquad ( 9 b )$$

With expressions (8b-8c) for 2^{nd} or higher order, and (9b) for odd-order baseband designs, any order baseband design can be translated into a non-zero center frequency BSF equivalent design, that is then suitable for circuit implementation discussed in subsequent sections.

3. Exact NGD Transfer Function Implementation with Sallen-Key Circuit Topology

A Sallen-Key topology is depicted in the FIG. 4 schematic, up to the output terminal of the op-amp, with the output resonator with impedance Z₃ cascaded in addition. The overall topology in FIG. 4 can achieve the 3^{rd}-order reciprocal-Butterworth baseband transfer function, translated to higher center frequency ω₀ as given by expression (7b).

The corresponding transfer function of the topology in FIG. 4 (Vin is assumed to be an ideal/buffered source, and Vout is assumed to be terminated in system impedance Z₀), and its input impedance (disregarding the optional input impedance matching resistor, Rₘ, which can be used with a non-ideal/non-buffered source) are given by, respectively:

$$H ( j ω ) = \frac{{V}_{out}}{{V}_{i n}} = \frac{{R}_{G} \cdot {R}_{F}}{{R}_{G} \cdot {R}_{F} + {Z}_{1} \cdot {Z}_{2} + {R}_{F} \cdot ( {Z}_{1} + {Z}_{2} )} \cdot \frac{{Z}_{0}}{{Z}_{0} + {Z}_{3}} , \qquad ( 10 )$$

$${Z}_{i n} = \frac{{R}_{G} \cdot {R}_{F} + {Z}_{1} \cdot {Z}_{2} + {R}_{F} \cdot ( {Z}_{1} + {Z}_{2} )}{{R}_{F} + {Z}_{2}} . \qquad ( 11 )$$

Expression (7b), associated with translating a 3^{rd}-order reciprocal-Butterworth baseband function with out-of-band gain A=100 (40 dB) and 3-dB cut-off frequency ωc to a higher center frequency ω₀=10ω_{c}, can be used as an implementation example for the topology in FIG. 4. Parameters of transfer function (7b) are summarized below:

$${ω}_{01 p} = 10.9 \; 046 {ω}_{c} , Δ {ω}_{1 p} = 1.0 \; 864 {ω}_{c} , \qquad ( 12 a )$$

$${ω}_{03 p} = 9.1 \; 704 {ω}_{c} , Δ {ω}_{3 p} = 0.9 \; 136 {ω}_{c} ,$$

$${ω}_{02 p} = 14.9 \; 294 {ω}_{c} , Δ {ω}_{2 p} = 6.4 \; 081 {ω}_{c} , {ω}_{04 p} = 6.6 \; 982 {ω}_{c} , Δ {ω}_{4 p} = 2.8 \; 75 {ω}_{c} , \qquad ( 12 b )$$

$${ω}_{0} = 10 {ω}_{c} , {Δω}_{5 p} = 2 {ω}_{c} , {Δω}_{6 p} = 2 {A}^{1 / 3} = 9.2 \; 832 {ω}_{c} . \qquad ( 12 c )$$

The component values of the design in FIG. 4 are obtained by equating the Sallen-Key transfer function (10), with the BSF transfer function (7b) and its parameters given by (12a-12c). The design component values calculation is demonstrated for a chosen center frequency design at f₀=10f_{c}=500 MHz, thus yielding a bandwidth of Δf=2f_{c}=100 MHz (20%) in this example. First, a desired input impedance at center frequency is chosen, in this example Zᵢₙ≈10Z₀=500Ω, such that loading effects are relatively small when a non-buffered source is used (or, if a shunt resistor Rₘ from FIG. 4 is used to match the design closer to a non-buffered source impedance Z₀ within the bandwidth, having Zᵢₙ>>Z₀ ensures the desired transfer function will not be affected considerably). Circuit component values are then calculated as:

$${R}_{1} \approx {Z}_{in} = 500 Ω , {C}_{1} = \frac{1}{{Δω}_{1 p} {R}_{1}} = 5.86 pF , \\ {L}_{1} = \frac{1}{{ω}_{01 p}^{2} {C}_{1}} = 14.541 nH , \qquad ( 13 a )$$

$${R}_{2} = {R}_{1} = 500 Ω , {C}_{2} = \frac{1}{{Δω}_{3 p} {R}_{2}} = 6.968 pF , \\ {L}_{2} = \frac{1}{{ω}_{03 p}^{2} {C}_{2}} = 17.29 nH , \qquad ( 13 b )$$

$${R}_{G} = \frac{1 / {C}_{1} + 1 / {C}_{2}}{{Δω}_{2 p} + {Δω}_{4 p} - {Δω}_{1 p} - {Δω}_{3 p}} = 137.3 Ω , \qquad ( 13 c )$$

$$\begin{matrix}{R}_{F} = \frac{1}{\begin{matrix}( {ω}_{02 p}^{2} + {ω}_{04 p}^{2} + {Δω}_{2 p} {Δω}_{4 p} - {ω}_{01 p}^{2} - {ω}_{03 p}^{2} - \\ {Δω}_{1 p} {Δω}_{3 p} ) {R}_{G} {C}_{1} {C}_{2} - \frac{2}{{R}_{1}^{2}}\end{matrix}} \\ = 24.11 Ω\end{matrix} . \qquad ( 13 d )$$

$${R}_{3} = {Z}_{0} ( {A}^{\frac{1}{3}} - 1 ) = 182.08 Ω , \\ {C}_{3} = \frac{1}{{Δω}_{5 p} {R}_{3}} = 8.741 pF , {L}_{3} = \frac{1}{{ω}_{0}^{2} {C}_{3}} = 11.592 nH . \qquad ( 13 e )$$

Tuned frequencies of the two resonators at the input op-amp input of the topology in FIG. 4, in this case are f₀₁_{ₚ}=10.9046f_{c}=545.23 MHZ, and f₀₃_{ₚ}=9.1704f_{c}=458.52 MHz, as given by (12a). The remaining 1st-order term in (7a), and its corresponding term in the design around higher center frequency given by (9b) and parameter values (12c), is implemented with a resonator at the op-amp output in FIG. 4. This resonator is tuned at the overall design center frequency f₀=500 MHZ, and the component values are calculated by (13e).

For designs with an order higher than 3^{rd} order detailed above, each 2^{nd} order baseband term in expressions (2a) or (2b) translates into higher center frequency form a product of two 2^{nd} order functions given by (8c), and those can be implemented by a Sallen-Key design depicted in the FIG. 4 schematic, up to the output terminal of the op-amp and connected in cascade. Finally, for odd-order designs, the final 1st order baseband stage in expression (2b) translates into higher center frequency 2^{nd} order function form given by (9b), and it can be implemented by a resonator at the output of the final cascaded stage Sallen-Key op-amp, similar as depicted in FIG. 4, at the op-amp output.

4. Approximate Implementation with RLC resonators in a Passive Ladder Topology

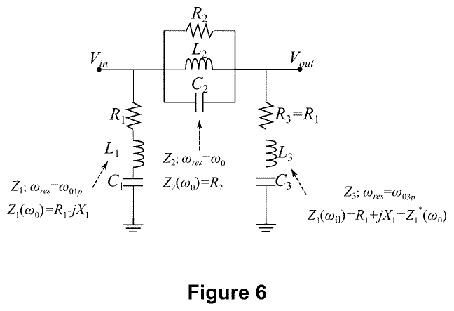

FIG. 6 illustrates a three-resonator π-circuit, that can achieve an approximate implementation of the transfer function given by (7b). This circuit can also be transformed into its T-circuit equivalent, such that series resonators connected in shunt would be replaced by parallel resonators connected in series, and vice versa. Relationship between equivalent series and parallel resonators components can be derived as: Rₚ=Z₀²/Rₛ, Lₚ=Z₀²·Cₛ, and Cₚ=Lₛ/Z₀², which also yields Zₚ(ω)=Z₀²/Zₛ(ω).

Transfer function of the design shown in FIG. 6, assuming it is driven by a Z₀-impedance source and terminated in a Z₀-impedance load, is given by:

$$H ( j ω ) = \frac{{V}_{out}}{{V}_{in}} = \frac{2}{( 1 + {Z}_{2} / {Z}_{0} + {Z}_{2} / {Z}_{3} ) \cdot ( 1 + {Z}_{0} / {Z}_{1} ) + ( 1 + {Z}_{0} / {Z}_{3} )} . \qquad ( 14 )$$

After expanding transfer function (14) impedances into their frequency dependent components, it can be shown that (14) becomes a 6^{th}-order rational transfer function of frequency. When (14) is factorized into three 2^{nd}-order product terms, it becomes clear that the numerator can be matched exactly to the transfer function (7b), by selecting the three resonators' center frequencies to match the corresponding ones in (7b), as labeled in FIG. 6. Further, for the numerators of expressions (7b) and (14) to match, the three resonators' bandwidths also need to be matched to the corresponding ones is (7b), as: Δ_{ω1}_{ₚ}=R₁/L1, Δ_{ω5}_{ₚ}=1/(R₂C₂), and Δ_{ω3}_{ₚ}=R₃/L3.

With the transfer function numerator matching of (7b) and (14) in mind, the only degree of freedom in FIG. 6 topology are the three resonators resistor values. Further, it can be shown that to satisfy the transfer function value/attenuation requirement at the center frequency H(jω₀)=1/A, a purely real number, shunt impedances Z₁ and Z₃ need to have their imaginary parts equal in magnitude and opposite in sign, at ω₀. It can be shown that this is only possible if R₃=R₁, and then the imaginary parts of Z₁ and Z₃ at ω₀ are:

$${X}_{1} = - Im \{ {Z}_{1} ( {ω}_{0} ) \} = {X}_{3} = \frac{1}{{ω}_{0} {C}_{1}} - {ω}_{0} {L}_{1} = ( \frac{{ω}_{01 p}^{2}}{{ω}_{0}} - {ω}_{0} ) \frac{{R}_{1}}{{Δω}_{1 p}} . \qquad ( 15 )$$

Further, for the transfer function attenuation at the center frequency to be exactly H(jω₀)=1/A, it can be derived that the middle resonator resistance is not independent, and instead given by:

$${R}_{2} = 2 \frac{( A - 1 ) ( {R}_{1}^{2} + {X}_{1}^{2} ) - {Z}_{0} {R}_{1}}{( {R}_{1}^{2} + {X}_{1}^{2} ) / {Z}_{0} - 2 {R}_{1} + {Z}_{0}} , \qquad ( 16 )$$

From (16), the only degree of freedom is the shunt resonators resistance value R₁, given the match of the numerator of expanded version of (14) to the numerator of the reciprocal-capped Butterworth NGD transfer function (7b), and given required center frequency attenuation of 1/A.

Since the exact transfer function match is not possible with this topology, an additional optimization criterion can be used to ensure a good in-band transfer function match. Since a characteristic of Butterworth filters is magnitude response flatness within a frequency band of interest, that feature is selected here to determine the optimal value R₁. Thus, by selecting the magnitude response curvature, or 2^{nd} derivative, closest to zero at the center frequency, an optimal value R₁=5.246862 is obtained in this example (reasonable initial guess value for R₁ corresponds to a single shunt resonator design which would have a center frequency attenuation of 1/A^{1/3}, i.e. R₁-initial=Z₀/(2 (A^{1/3}−1))=6.865Ω).

Substituting the optimized R₁=5.2468Ω value into expressions (15) and (16), yields X₁=9.133Ω and R₂=341.8909Ω, respectively. All component values corresponding to the design in FIG. 6 in this example with A=100, f₀=500 MHZ, f_{c}=50 MHz, are:

$${R}_{1} = 5.2468 Ω , {L}_{1} = \frac{1}{{Δω}_{1 p} {R}_{1}} = 15.373 nH , \\ {C}_{1} = \frac{1}{{ω}_{01 p}^{2} {L}_{1}} = 5.5428 pF , \qquad ( 17 a )$$

$${R}_{3} = 5.2468 Ω , {L}_{3} = \frac{1}{{Δω}_{3 p} {R}_{3}} = 18.281 nH , \\ {C}_{3} = \frac{1}{{ω}_{03 p}^{2} {L}_{3}} = 6.5908 pF , \qquad ( 17 b )$$

$${R}_{2} = 341.8909 Ω , {C}_{2} = \frac{1}{2 {ω}_{c} {R}_{2}} = 4.6551 pF , \\ {L}_{2} = \frac{1}{{ω}_{0}^{2} {C}_{2}} = 21.765 nH . \qquad ( 17 c )$$

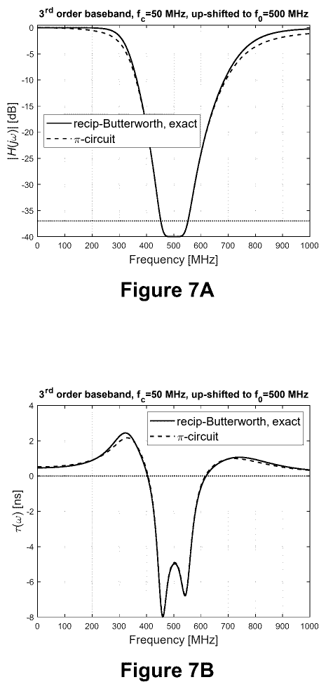

Transfer function magnitude and group delay responses of the topology depicted in FIG. 6, are shown in FIG. 7.

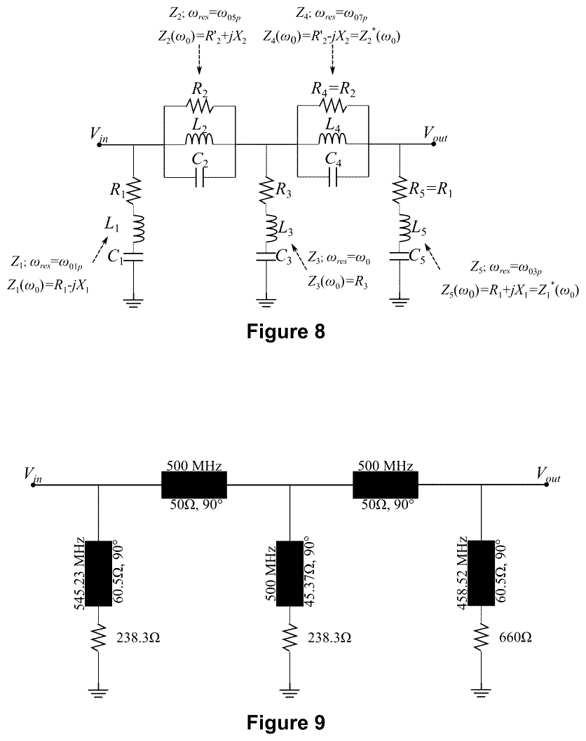

To demonstrate ladder design extension to higher orders, a 5^{th}-order proposed reciprocal-Butterworth baseband design translated to a higher center frequency can be approximately implemented by an all-passive five-resonator ladder topology shown in FIG. 8.

Following similar derivations to those associated with the three-resonator π-circuit design, it can be shown that to match the numerator of the exact 5^{th}-order transfer function upshifted to higher center frequency, resonators in FIG. 8 need to have their center frequencies and bandwidths matched to those in the non-zero center frequency equivalent of baseband transfer function (3e). Further, for the center frequency attenuation to be exactly 1/A, it can be shown via derivations similar to (15-16) and that R₅=R₁ and R₄=R₂ conditions need to be met, which in turn yield center frequency complex conjugate impedance values of corresponding resonators, as labeled in FIG. 8.

5. Approximate Implementation with Microwave Circuit Quarter-Wavelength Transmission Lines and Resistors Only

At microwave frequencies, where quarter-wavelength) (90° lines become sufficiently physically small to implement on a PCB design (microstrip line, or co-planar waveguide, CPW), the ladder network with lumped RLC resonators such as n-circuit in FIG. 6, can be approximated by quarter-wavelength lines/stubs and resistor components only, as depicted in FIG. 9. By using asymptotic expansion of a tan (x) function around quarter-wavelength frequency, it can be shown that an input impedance of a resistive-terminated transmission line can approximate series RLC resonators connected in shunt in the π-circuit from FIG. 6 (a 1st order approximation), with the 90°-line (at resonator center frequency) characteristic impedance and terminating resistance given by:

$${Z}_{c 1} = \frac{1}{π} ( 2 \sqrt{{L}_{1} / {C}_{1}} + \sqrt{4 {L}_{1} / {C}_{1} - {( {R}_{1} π )}^{2}} ) = 66.6 Ω , \\ {R}_{L 1} = {Z}_{c 1}^{2} / {R}_{1} = 846.4 Ω \qquad ( 18 a )$$

$${Z}_{c 3} = \frac{1}{π} ( 2 \sqrt{{L}_{3} / {C}_{3}} + \sqrt{4 {L}_{3} / {C}_{3} - {( {R}_{3} π )}^{2}} ) = 66.6 Ω , \\ {R}_{L 3} = {Z}_{c 3}^{2} / {R}_{3} = 846.4 Ω \qquad ( 18 b )$$

As for the parallel RLC resonator connected in series, in FIG. 6, to facilitate a convenient shunt stub implementation, the resonator is first transformed into a shunt series RLC resonator with two series 90°-lines introduced on each side of it, with the series resonator replaced by a stub similar to the other two, with:

$${Z}_{c 2} = \frac{{Z}_{0}^{2}}{π} ( 2 \sqrt{{C}_{2} / {L}_{2}} + \sqrt{4 {C}_{2} / {L}_{2} - {( π / {R}_{2} )}^{2}} ) = 45.4 Ω , \\ {R}_{L 2} = {R}_{2} \cdot {Z}_{c 2}^{2} / {Z}_{0}^{2} = 281.5 Ω \qquad ( 18 c )$$

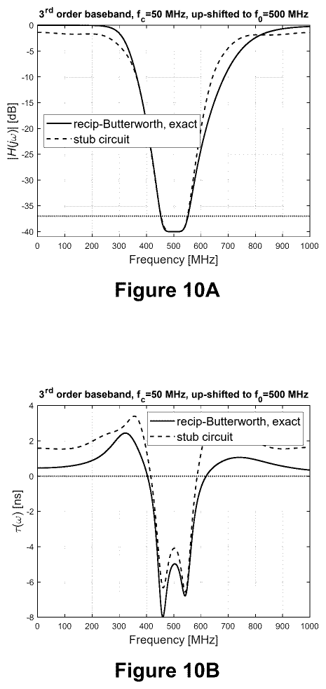

The values calculated in (18a-18c) in this example need to be optimized, since the RLC resonators are replaced by stubs individually, in isolation. However, the three stubs are interacting with each other following different functions of frequency, compared to the lumped RLC resonators. Therefore, to optimize for the flat in-band magnitude response of the transfer function, the stub design parameters values are varied around the initial-guess values described by (18a -18c), yielding (magnitude and group delay plots shown in FIG. 10):

$${Z}_{c 1} = {Z}_{c 3} = 60.5 Ω , {R}_{L 1} = 835 Ω , {R}_{L 3} = 660 Ω , \qquad ( 19 a )$$

$${Z}_{c 2} = 45.4 Ω , {R}_{L 2} = 238.3 Ω . \qquad ( 19 b )$$

6. Reciprocal-Capped Chebyshev Design Variation (its Baseband Transfer Function Replaces the One in Section 1, then the Same Process Followed as in Sections 2-5 to Implement)

Instead of the Reciprocal-capped Butterworth baseband transfer function presented in Section 1, another novel NGD transfer function presented below is based on a reciprocal function of a classic N^{th} order low-pass Chebyshev filter transfer function with a given pass-band ripple factor, ε, (between 0 and 1), multiplied by its corresponding “capping” function, which is another N^{th} order low-pass Chebyshev filter transfer function but with a smaller ripple, ε/A (wider bandwidth relative to the first one), where A is the desired out-of-band gain as before:

$$H ( j ω ) = \frac{1}{{H}_{LP - ripple - ε} ( j ω )} \cdot {H}_{LP - ripple - ε / A} ( j ω ) . \qquad ( 20 )$$

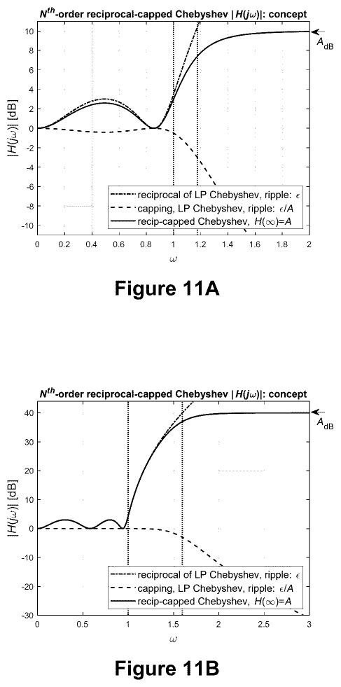

The concept of such novel NGD reciprocal-capped Chebyshev filter transfer function, is captured in the example magnitude plots in FIG. 11. The final transfer functions, shown in red, exhibit the minimum/lower values at the zero-center frequency (and within the baseband) compared to out-of-band magnitude A, while at the same having a rippled magnitude response (chosen to be between 0 dB and 3 dB) within the bandwidth around the center frequency, which is characteristic to Chebyshev filters.

From expression (20), using the transfer function expressions of classic Chebyshev low-pass filters, the novel NGD design for odd values of the order N (even number values are found to yield NGD values lower than reciprocal-Butterworth design from Section 1, and therefore are not considered here), are given respectively as (frequency ω in the expressions below is normalized to user-specified cut-off frequency value ω_{c}=2π·Δf/2):

$${H}_{N - odd} ( j ω ) = A \frac{ω - j \cdot {k}_{1}}{ω - j \cdot {k}_{1}^{′}} {\prod }_{k = 1}^{( N - 1 ) / 2} ( \frac{\begin{matrix}{ω}^{2} - j \cdot 2 {k}_{1} \cdot sin ( \frac{2 k - 1}{2 N} π ) ω - \\ ( {k}_{1}^{2} {sin}^{2} ( \frac{2 k - 1}{N} \frac{π}{2} ) + {k}_{2}^{2} {cos}^{2} ( \frac{2 k - 1}{N} \frac{π}{2} ) )\end{matrix}}{\begin{matrix}{ω}^{2} - j \cdot 2 {k}_{1}^{′} \cdot sin ( \frac{2 k - 1}{2 N} π ) ω - \\ ( {k}_{1}^{′2} {sin}^{2} ( \frac{2 k - 1}{N} \frac{π}{2} ) + {k}_{2}^{′2} {cos}^{2} ( \frac{2 k - 1}{N} \frac{π}{2} ) )\end{matrix}} ) , \qquad ( 21 )$$

where the factorized functions' parameters are as in N^{th}-order Chebyshev low-pass filter (desired passband ripple given in decibels is R_{dB}, with values between 0 dB and 3 dB):

$$ε = \sqrt{{10}^{( {R}_{dB} / 10 )} - 1} , \qquad ( 22 a )$$

$$\begin{matrix}{k}_{1} = sinh ( \frac{1}{N} \cdot {sinh}^{- 1} ( \frac{1}{ε} ) ) & {k}_{2} = cosh ( \frac{1}{N} \cdot {sinh}^{- 1} ( \frac{1}{ε} ) )\end{matrix} , \qquad ( 22 b )$$

$$\begin{matrix}{k}_{1}^{′} = sinh ( \frac{1}{N} \cdot {sinh}^{- 1} ( \frac{A}{ε} ) ) & {k}_{2}^{′} = cosh ( \frac{1}{N} \cdot {sinh}^{- 1} ( \frac{A}{ε} ) )\end{matrix} , \qquad ( 22 c )$$

A frequency correction factor is needed to yield the overall transfer function 3 dB magnitude value at ω=1, which is achieved by replacing ω by ω/C_{ω-3dB}, in H(jω) expression (21), where:

$${C}_{ω - 3 dB} = cosh ( \frac{1}{N} \cdot {cosh}^{- 1} ( \frac{1}{ε \sqrt{1 - 2 / {A}^{2}}} ) ) . \qquad ( 23 )$$

For example, if A=100 (40 dB) and order N=3, then the correction factor for 3 dB ripple (8=1) yields C_{ω-3dB}≈1.0, while 1 dB ripple (ε=0.5088) yields C_{ω-3dB}=1.0949, and 0.5 dB ripple (ε=0.3493) yields C_{ω-3dB}=1.1675.

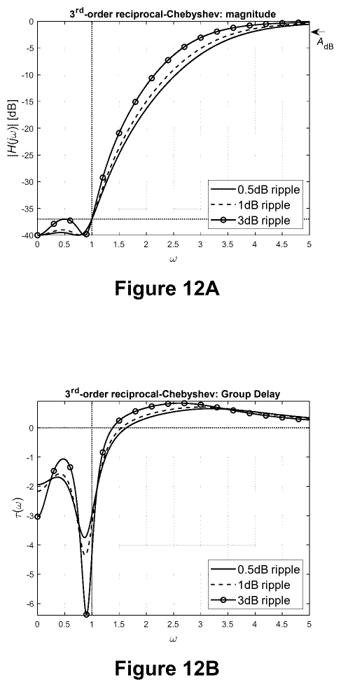

From expressions (21-23), after division by assumed out-of-band gain A=100 (40 dB) to get a purely passive design, transfer functions for three example 3^{rd}-order reciprocal-Chebyshev designs (0.5 dB, 1 dB and 3 dB baseband ripple) are given by expressions (24a-24c), and corresponding magnitude and group delay plots are shown in FIG. 12.

$${H}_{3 rd - 0.5 dB} ( j ω ) = ( \frac{ω - j \cdot 0.6265}{ω - j \cdot 4.0916} ) \cdot ( \frac{{ω}^{2} - j \cdot 0.6265 ω - {1.0689}^{2}}{{ω}^{2} - j \cdot 4.0916 ω - {4.1823}^{2}} ) . \qquad ( 24 a )$$

$${H}_{3 rd - 1 dB} ( j ω ) = ( \frac{ω - j \cdot 0.4389}{ω - j \cdot 3.2494} ) \cdot ( \frac{{ω}^{2} - j \cdot 0.4389 ω - {0.9104}^{2}}{{ω}^{2} - j \cdot 3.2494 ω - {3.3458}^{2}} ) . \qquad ( 24 b )$$

$${H}_{3 rd - 3 dB} ( j ω ) = ( \frac{ω - j \cdot 0.298}{ω - j \cdot 2.8385} ) \cdot ( \frac{{ω}^{2} - j \cdot 0.298 ω - {0.9159}^{2}}{{ω}^{2} - j \cdot 2.8385 ω - {2.9677}^{2}} ) , \qquad ( 24 c )$$

The group delay at the center frequency, as a function of the out-of-band gain A, circuit order N, and passband ripple &, is derived to be (in combination with expressions 22-23):

$$τ ( 0 ) = - \frac{1}{{C}_{ω - 3 dB}} [ ( \frac{1}{{k}_{1}} - \frac{1}{{k}_{1}^{′}} ) + {\sum }_{k = 1}^{( N - 1 ) / 2} ( \frac{2 {k}_{1} sin ( \frac{2 k - 1}{N} \frac{π}{2} )}{{k}_{1}^{2} + {cos}^{2} ( \frac{2 k - 1}{N} \frac{π}{2} )} - \frac{2 {k}_{1}^{′} sin ( \frac{2 k - 1}{N} \frac{π}{2} )}{{k}_{1}^{′2} + {cos}^{2} ( \frac{2 k - 1}{N} \frac{π}{2} )} ) ] . \qquad ( 25 )$$

In the FIG. 12b) examples with A=100 (40 dB) and N=3, expression (25) yields center frequency NGD values, NGD=−τ(0)=1.9454s, 2.1673s, 3.0360s for passband ripple R_{dB}=0.5, 1, and 3 dB, respectively. All three reciprocal-Chebyshev examples above yield a higher center frequency NGD compared to the corresponding (A=40 dB, N=3) reciprocal-Butterworth value of 1.5692s, as presented in Section 1.

In essence, very low ripple (close to 0 dB) reciprocal-Chebyshev case would be equivalent to reciprocal-Butterworth case of the same order N and out-of-band gain A, and then as the ripple is increased towards the maximum of 3 dB, the center frequency NGD is increased from 1.5692s to a maximum of 3.0360s, in this example.

The increased center frequency NGD of reciprocal-Chebyshev design (Section 6), compared to reciprocal-Butterworth design (Section 1) for the same order N and out-of-band gain A, comes at the expense of larger group delay variation within the passband (FIG. 12b vs FIG. 2b for order N=3). The increased group delay variation within the passband (between normalized frequencies of 0 and 1.0) can result in increased distortion of propagated waveforms in the time domain. Therefore, reciprocal-Chebyshev design is not by default a better design (higher NGD) compared to reciprocal-Butterworth: just like in classic low-pass versions, one is chosen over the other given the specific application in mind.

For reciprocal-Chebyshev design presented in Section 6, subsequent steps towards actual circuit/device implementation are the same as outlined in Sections 2-5; the only difference is that initial baseband functions such as those in expressions (24), are used instead of reciprocal-Butterworth expressions (3) for example.

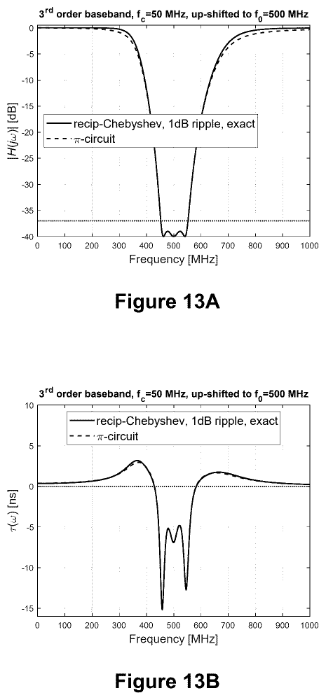

The only additional note is for topology presented in Section 4, where the optimization criterion for reciprocal-Butterworth design is described as: “ . . . by selecting the magnitude response curvature, or 2^{nd} derivative, closest to zero at the center frequency”. For reciprocal-Chebyshev design, the optimization criterion needs to be replaced with: “ . . . by selecting the magnitude response curvature, or 2^{nd} derivative, closest to the actual non-zero curvature at the center frequency”. An example is shown in FIG. 13, a counterpart to FIG. 7.

Following the described optimization procedure, yields the following components values for the circuit topology given in Section 4, FIG. 6, which produce the reciprocal-capped Chebyshev filter response shown in FIG. 13:

$${R}_{1} = 3.3894 Ω , {L}_{1} = \frac{1}{{Δω}_{1 p} {R}_{1}} = 21.9743 nH , \\ {C}_{1} = \frac{1}{{ω}_{01 p}^{2} {L}_{1}} = 3.8657 pF , \qquad ( 26 a )$$

$${R}_{3} = 3.3894 Ω , {L}_{3} = \frac{1}{{Δω}_{3 p} {R}_{3}} = 26.2102 nH , \\ {C}_{3} = \frac{1}{{ω}_{03 p}^{2} {L}_{3}} = 4.6109 pF , \qquad ( 26 b )$$

$${R}_{2} = 611.0588 Ω , {C}_{2} = \frac{1}{2 {Δω}_{1} {R}_{2}} = 5.7713 pF , \\ {L}_{2} = \frac{1}{{ω}_{0}^{2} {C}_{2}} = 17.5561 nH . \qquad ( 26 c )$$

The scope of the claims should not be limited by the preferred embodiments set forth in the examples but should be given the broadest interpretation consistent with the description as a whole.

1. A synthesized general Negative Group Delay (NGD) prototype filter transfer function of a given order greater or equal to 1, exhibiting a maximal flatness of magnitude response within a 3 dB bandwidth at Baseband, Around Zero Frequency as in classical Butterworth filters while also exhibiting a negative group delay;
said synthesized general NGD transfer function having a “Reciprocal-capped Butterworth” transfer function design;
said Reciprocal-capped Butterworth transfer function of a given order being synthesized as a ratio of two classical Butterworth filter transfer functions of the same order, each having a different individual 3 dB bandwidth;
said different individual 3 dB bandwidths being related to defined properties of the Reciprocal-capped Butterworth transfer function, such as 3 dB bandwidth, NGD at center frequency, and out-of-band gain.

2. A general Negative Group Delay (NGD) transfer function (Around Non-Zero Frequency) version of reciprocal-capped Butterworth prototype design of a given order according to claim 1;
said version of the general NGD transfer function being obtained by a mathematical transformation of the frequency variable which is present in the general NGD transfer function, to obtain a similar shape and properties as in claim 1, around a Non-Zero Frequency instead of Baseband.

3. The general negative group delay circuit according to claim 2 comprising an Exact NGD Transfer Function (Around Non-Zero Frequency) Implementation of reciprocal-capped Butterworth design of a 3^{rd} order, by employing RLC resonators in a Sallen-Key Circuit Topology;
said Sallen-Key negative group delay circuit comprising the first parallel RLC resonator (R1, L1, C1) component;
said Sallen-Key negative group delay circuit further comprising the second parallel RLC resonator (R2, L2, C2) component with the first RLC resonator component being arranged between an input port of the Sallen-Key negative group delay circuit and the second parallel RLC resonator component;
said second parallel RLC resonator component being arranged between the first parallel RLC resonator component and the positive input terminal of an operational amplifier (op-amp);
a resistor component (RG) being arranged between the said positive input terminal of the op-amp and the circuit ground;
another resistor component (RF) being arranged between the negative terminal of the said op-amp, and the junction point between the said first and second RLC resonator components;
said negative terminal of the op-amp being connected to the op-amp output,
the third parallel RLC resonator (R3, L3, C3) being arranged between the op-amp output and the output port of the Sallen-Key negative group delay circuit.

4. The general negative group delay circuit according to claim 2, comprising an Approximate NGD Transfer Function (Around Non-Zero Frequency) Implementation of reciprocal-capped Butterworth design of a 3^{rd} order, by employing RLC resonators in a Passive Ladder Topology;
said passive ladder topology negative group delay circuit comprising the first series RLC resonator (R1, L1, C1) component being arranged between an input port of the negative group delay circuit and the ground;
said passive ladder topology negative group delay circuit further comprising a parallel RLC resonator (R2, L2, C2) component being arranged between the input port and the output port of the negative group delay circuit; and
the second series RLC resonator (R3, L3, C3) component being arranged between the output port of the negative group delay circuit and the ground.

5. The general negative group delay circuit according to claim 2, comprising an Approximate NGD Transfer Function (Around Non-Zero Frequency) Implementation of reciprocal-capped Butterworth design of 3^{rd} order, by employing Microwave Circuit Quarter-Wavelength Transmission Lines and Resistors;
said negative group delay circuit comprising the first Quarter-Wavelength transmission line component being arranged between an input port of the negative group delay circuit and the first resistor;
said first resistor being arranged between the said first Quarter-Wavelength transmission line and the circuit ground;
said second Quarter-Wavelength transmission line component being arranged between the input port of the negative group delay circuit and the third Quarter-Wavelength transmission line;
said third Quarter-Wavelength transmission line being arranged between the said second Quarter-Wavelength transmission line, and the negative group delay circuit output port;
the fourth Quarter-Wavelength transmission line being arranged between the junction of the second and third Quarter-Wavelength transmission lines, and a second resistor;
said second resistor being arranged between the said fourth Quarter-Wavelength transmission line and the circuit ground;
the fifth Quarter-Wavelength transmission line being arranged between the negative group delay circuit output port and a third resistor,
said third resistor being arranged between the said fifth Quarter-Wavelength transmission line and the circuit ground.

6. A synthesized general Negative Group Delay (NGD) transfer function (prototype filter) exhibiting a rippled magnitude response within the 3 dB bandwidth (at Baseband, Around Zero Frequency) as in classical Chebyshev filters while also exhibiting a negative group delay. said synthesized transfer function (design) being referred to herein as “Reciprocal-capped Chebyshev” transfer function (design);
said Reciprocal-capped Chebyshev transfer function of a given order is synthesized as a ratio of two classical Chebyshev filter transfer functions of the same order, each having a different individual ripple magnitude within their 3 dB bandwidths;
said two ripple magnitudes are related to the defined properties of the synthesized Reciprocal-capped Butterworth transfer function, such as 3 dB bandwidth, NGD at center frequency, and out-of-band gain, as detailed in the invention description.

7. The general Negative Group Delay (NGD) Transfer Function (Around Non-Zero Frequency) version of reciprocal-capped Chebyshev design prototype design according to claim 6, said version of the transfer function is obtained by a mathematical transformation of the frequency variable which is present in the transfer function, to obtain similar shape and properties, around a Non-Zero Frequency instead of Baseband.

8. The general negative group delay circuit according to claim 7 comprising an Exact NGD Transfer Function (Around Non-Zero Frequency) Implementation of reciprocal-capped Chebyshev design of a 3^{rd} order, by employing RLC resonators in a Sallen-Key Circuit Topology;
said Sallen-Key negative group delay circuit comprising the first parallel RLC resonator (R1, L1, C1) component;
said Sallen-Key negative group delay circuit also comprising the second parallel RLC resonator (R2, L2, C2) component with the first RLC resonator component being arranged between an input port of the Sallen-Key negative group delay circuit and the second parallel RLC resonator component;
said second parallel RLC resonator component being arranged between the first parallel RLC resonator component and the positive input terminal of an operational amplifier (op-amp);
a resistor component (RG) being arranged between the said positive input terminal of the op-amp and the circuit ground;
another resistor component (RF) being arranged between the negative terminal of the said op-amp, and the junction point between the said first and second RLC resonator components;
said negative terminal of the op-amp being connected to the op-amp output;
said third parallel RLC resonator (R3, L3, C3) being arranged between the op-amp output and the output port of the Sallen-Key negative group delay circuit.

9. The general negative group delay circuit according to claim 7, comprising an Approximate NGD Transfer Function (Around Non-Zero Frequency) Implementation of reciprocal-capped Chebyshev design of a 3^{rd} order, by employing RLC resonators in a Passive Ladder Topology;
said passive ladder topology negative group delay circuit comprising the first series RLC resonator (R1, L1, C1) component being arranged between an input port of the negative group delay circuit and the ground;
said passive ladder topology negative group delay circuit also comprising a parallel RLC resonator (R2, L2, C2) component being arranged between the input port and the output port of the negative group delay circuit;
and the second series RLC resonator (R3, L3, C3) component being arranged between the output port of the negative group delay circuit and the ground.

10. The general negative group delay circuit according to claim 7, comprising an Approximate NGD Transfer Function (Around Non-Zero Frequency) Implementation of reciprocal-capped Chebyshev design of a 3^{rd} order, by employing Microwave Circuit Quarter-Wavelength Transmission Lines and Resistors;
said negative group delay circuit comprising the first Quarter-Wavelength transmission line component being arranged between an input port of the negative group delay circuit and the first resistor;
said first resistor being arranged between the said first Quarter-Wavelength transmission line and the circuit ground;
said second Quarter-Wavelength transmission line component being arranged between the input port of the negative group delay circuit and the third Quarter-Wavelength transmission line;
said third Quarter-Wavelength transmission line being arranged between the said second Quarter-Wavelength transmission line, and the negative group delay circuit output port;
said fourth Quarter-Wavelength transmission line being arranged between the junction of the second and third Quarter-Wavelength transmission lines, and a second resistor; said second resistor being arranged between the said fourth Quarter-Wavelength transmission line and the circuit ground;
said fifth Quarter-Wavelength transmission line being arranged between the negative group delay circuit output port and a third resistor;
said third resistor being arranged between the said fifth Quarter-Wavelength transmission line and the circuit ground.
